(19) United States
(12) Patent Application Publication
(10) Pub. No.: US 2024/0220570 A1
(43) Pub. Date: Jul. 4, 2024

(54) METHOD AND APPARATUS FOR LEARNING FAULT SIGNAL DETECTION BASED ON COMBINATION OF FREQUENCY BAND DECOMPOSITION SIGNALS

(71) Applicant: AJOU UNIVERSITY INDUSTRY-ACADEMIC COOPERATION FOUNDATION, Suwon-si (KR)

(72) Inventors: Jung Won LEE, Seoul (KR); Min Seo CHOI, Anseong-si (KR); Dong Yeon YOO, Suwon-si (KR)

(21) Appl. No.: 18/535,013

(22) Filed: Dec. 11, 2023

(30) Foreign Application Priority Data
Jan. 2, 2023 (KR) 10-2023-0000209

(51) Int. Cl. G06F 17/14; G06F 18/2131

(52) U.S. Cl. CPC G06F 17/142; G06F 18/2131; G06F 2218/08; G06F 2218/12

(57) ABSTRACT

A fault signal detection method includes acquiring decomposition signals according to a frequency band, by decomposing an original signal in the time domain into a certain number of frequency band signals, combining the certain number of decomposition signals and calculating a classification result value for classifying the original signal into a normal signal or a fault signal using a classification model using at least one decomposition signal included in a combination method as input and determining a combination method for detecting a fault signal based on classification result values of the classification model.

### CROSS REFERENCE TO RELATED APPLICATION

The present application claims priority to Korean Patent Application No. 10-2023-0000209 filed on Jan. 2, 2023, the entire contents of which is incorporated herein for all purposes by this reference.

### BACKGROUND

### 1. Field of the Invention

The present disclosure relates to fault signal detection technology, and more specifically, to a method and apparatus for determining an optimal decomposition signal combination among frequency band decomposition signals and detecting a fault signal using a classification model based on the optimal decomposition signal combination.

### 2. Description of the Related Art

Compared to the time domain, the frequency domain contains various features of data such as amplitude, peak frequency, natural frequency, and frequency energy, and is advantageous in extracting data features. Therefore, a signal decomposition technique, which decomposes a frequency domain signal into several parts and then reconstructs them, is effective in terms of learning performance improvement.

In a conventional technology, assuming that a signal is composed of a plurality of intrinsic function modes (IMFs), the signal was decomposed by IMF. However, this technology can guarantee the uniqueness of the IMF only when the frequency scale of the decomposition signal is small.

In another conventional technology, a signal is simultaneously decomposed through non-recursive mode extraction, that is, an estimated center frequency, and there is a noise removal filter. However, this technology has large performance differences depending on the set bandwidth and number of decompositions, and it takes a lot of time to optimize internal filters and parameters.

In other words, although performance has been improved through existing studies, there are problems in terms of decomposition signal duplication, performance differences, and decomposition time.

### SUMMARY

An object of the present disclosure is to provide a method and apparatus for determining an optimal decomposition signal combination among frequency band decomposition signals and detecting a fault signal using a classification model based on the optimal decomposition signal combination.

The technical problems solved by the present disclosure are not limited to the above technical problems and other technical problems which are not described herein will be clearly understood by a person (hereinafter referred to as an ordinary technician) having ordinary skill in the technical field, to which the present disclosure belongs, from the following description.

A fault signal detection method according to an embodiment of present the disclosure includes acquiring decomposition signals according to a frequency band, by decomposing an original signal in the time domain into a certain number of frequency band signals, combining the certain number of decomposition signals and calculating a classification result value for classifying the original signal into a normal signal or a fault signal using a classification model using at least one decomposition signal included in a combination method as input and determining a combination method for detecting a fault signal based on classification result values of the classification model.

In this case, the combination method may include a method of adding at least one of the decomposition signals.

The fault signal detection method according to the embodiment of the present disclosure may further include determining a classification model learned by a decomposition signal of the determined combination method and detecting a fault signal using the determined classification model.

In this case, the decomposition signal of the determined combination method may include a high-frequency signal having a tendency to noise data among the decomposition signals according to the frequency band.

In this case, the decomposition signal of the determined combination method may include at least one of the remaining decomposition signals excluding a decomposition signal in a lowest frequency band and a decomposition signal in a highest frequency band among the decomposition signals according to the frequency band.

In this case, the acquiring the decomposition signals may include acquiring the certain number of decomposition signals by decomposing the original signal into uniform frequency bands.

In this case, the acquiring the decomposition signals may include acquiring the certain number of decomposition signals using a Fast Fourier Transform (FFT) technique.

In this case, the acquiring the decomposition signals may include acquiring the decomposition signals by reconstructing a negative frequency signal using a complex conjugate relationship of a frequency signal based on Real-valued FFT (RFFT) among the Fast Fourier Transform (FFT) techniques.

A fault signal detection method according to another embodiment of the present disclosure includes acquiring decomposition signals according to a frequency band by decomposing an original signal in the time domain into a certain number of frequency band signals, extracting at least one decomposition signal corresponding to a preset combination method from the decomposition signals and classifying the original signal into a normal signal or a fault signal, using a pre-learned classification model using the extracted at least one decomposition signal as input.

A fault signal detection apparatus according to another embodiment of the present disclosure includes an acquisition unit configured to acquire decomposition signals according to a frequency band, by decomposing an original signal in the time domain into a certain number of frequency band signals, a calculation unit configured to combine the certain number of decomposition signals and to calculate a classification result value for classifying the original signal into a normal signal or a fault signal using a classification model using at least one decomposition signal included in a combination method as input and a determination unit configured to determine a combination method for detecting a fault signal based on classification result values of the classification model.

The features briefly summarized above with respect to the present disclosure are merely exemplary aspects of the detailed description of the present disclosure described below, and do not limit the scope of the present disclosure.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a flowchart illustrating operation of a fault signal detection method according to an embodiment of the present disclosure;

FIG. 2 is a diagram illustrating an overall process of the method of the present disclosure;

FIG. 3 is a diagram illustrating a process of acquiring decomposition signals using FFT;

FIG. 4 is a diagram illustrating a combination method of decomposition signals;

FIG. 5 is a diagram illustrating a classification result value according to the combination method of decomposition signals;

FIG. 6 is a flowchart illustrating operation of a fault signal detection method according to another embodiment of the present disclosure;

FIG. 7 is a diagram illustrating a configuration of a fault signal detection apparatus according to another embodiment of the present disclosure; and

FIG. 8 is a diagram illustrating a configuration of a device, to which a fault signal detection apparatus is applied, according to another embodiment of the present disclosure.

### DETAILED DESCRIPTION

Hereinafter, with reference to the accompanying drawings, embodiments of the present disclosure will be described in detail so that those skilled in the art can easily practice them. However, the present disclosure may be implemented in many different forms and is not limited to the embodiments described herein.

In describing embodiments of the present disclosure, if it is determined that detailed descriptions of known configurations or functions may obscure the subject matter of the present disclosure, detailed descriptions thereof will be omitted. In addition, in the drawings, parts that are not related to the description of the present disclosure are omitted, and similar parts are given similar reference numerals.

In the present disclosure, when it is said that a component is “connected,” “coupled,” or “linked” to another component, this may include not only a direct connection relationship, but also an indirect connection relationship in which another component exists in between. In addition, when it is said that a component “include” or “have” another component, this does not mean excluding the other component, but may further include another component, unless specifically stated to the contrary.

In the present disclosure, terms such as first and second are used only for the purpose of distinguishing one component from other components, and do not limit the order or importance of the components unless specifically mentioned. Accordingly, within the scope of the present disclosure, a first component in one embodiment may be referred to as a second component in another embodiment, and similarly, a second component in one embodiment may be referred to as a first component in another embodiment.

In the present disclosure, distinct components are intended to clearly explain each feature, and do not necessarily mean that the components are separated. That is, a plurality of components may be integrated to form one hardware or software unit, or one component may be distributed to form a plurality of hardware or software units. Accordingly, even if not specifically mentioned, such integrated or distributed embodiments are also included in the scope of the present disclosure.

In the present disclosure, components described in various embodiments do not necessarily mean essential components, and some may be optional components. Accordingly, embodiments consisting of a subset of the components described in one embodiment are also included in the scope of the present disclosure. In addition, embodiments that include other components in addition to the components described in the various embodiments are also included in the scope of the present disclosure.

In the present disclosure, expressions of positional relationships used in this specification, such as top, bottom, left, right, etc., are described for convenience of explanation, and when the drawings shown in this specification are viewed in reverse, the positional relationships described in the specification may also be interpreted in reverse.

In the present disclosure, each of phrases such as “A or B”, “at least one of A and B”, “at least one of A or B”, “A, B or C”, “at least one of A, B and C”, and “at least one of A, B, or C” may include any one of the items listed together in the corresponding phrase, or any possible combination thereof.

To predict faults in industrial equipment, fault detection research using time series data from various sensors mounted on devices is expanding. However, if the features of the sensor's time series data are not clear, a difference between normal and fault signals is insufficient, making it difficult to detect faults. As a result, studies suggesting frequency domain signal decomposition techniques have emerged, but existing studies cannot guarantee the uniqueness of the decomposition signal, have large performance differences depending on parameters, and require a lot of time in the decomposition process due to parameter optimization and intrinsic filters.

Embodiments of the present disclosure decompose a signal into uniform frequency bands to prevent duplication of decomposition signals, determine an optimal decomposition signal combination among frequency band decomposition signals, and detect a fault signal using a classification model based on the optimal decomposition signal combination.

At this time, embodiments of the present disclosure can reduce time costs and eliminate the risk of signal loss due to reduction of calculation amount and parameters based on FFT (Fast Fourier Transform) in a signal decomposition process.

That is, embodiments of the present disclosure can detect faults in signals of time series data through decomposition and combination of signals, and learn a classification model using a combination of decomposition signals capable of deriving optimal results, thereby deriving an optimal result in detecting fault signals.

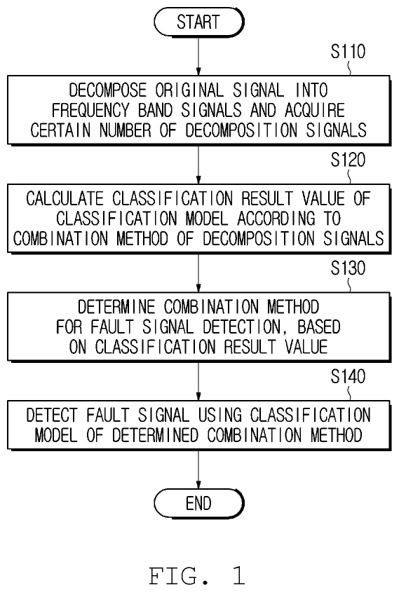

The method and apparatus according to the embodiment of the present disclosure will be described with reference to FIGS. 1 to 7, and an original signal in the embodiment of the present disclosure may mean a signal of time series data to detect a fault, and embodiments of the present disclosure can be applied to all types of time series data for classifying fault and normal.

FIG. 1 is a flowchart illustrating operation of a fault signal detection method according to an embodiment of the present disclosure.

Referring to FIG. 1, the fault signal detection method according to an embodiment of the present disclosure decomposes an original signal in the time domain, for example, an original signal of time series data, into a certain number of frequency band signals, and acquires decomposition signals according to the frequency band (S110).

In some embodiments, in step S110, after setting a sampling frequency, a normal signal or fault signal is decomposed into a certain number (for example, N) of uniform frequency band signals to acquire decomposition signals according to the frequency band. Through this process, the aspect of the decomposition signal for each frequency band may be analyzed, and the features of the fault may be extracted more clearly.

In some embodiments, in step S110, a certain number of decomposition signals may be acquired using a Fast Fourier Transform (FFT) technique. For example, in step S110, a negative frequency signal may be reconstructed using a complex conjugate relationship of the frequency signal based on Real-valued FFT (RFFT) among FFT techniques, thereby acquiring decomposition signals according to the uniform frequency band from the original signal.

When the decomposition signals according to the uniform frequency band are acquired in step S110, a certain number of decomposition signals are combined using preset combination methods, and a classification result value obtained by classifying the original signal into a normal signal or a fault signal is calculated using a classification model having at least one decomposition signal included in the combination method as input (S120).

At this time, in step S120, in the process of learning each classification model using the decomposition signal of each combination method as learning data, the classification result value output from the classification model of each combination method may be calculated.

In some embodiments, in step S120, the classification result value for each combination method may be calculated using each classification model using learning data for at least one decomposition signal combined according to the combination method.

In some embodiments, in step S120, the classification result value for each combination method may also be calculated using a specific classification model through learning data unrelated to the combination method.

Preferably, in step S120, the classification result value for each combination method is calculated through each classification model for each combination method.

Here, the combination method in step S120 may include a method of adding at least one decomposition signal among the decomposition signals.

When the classification result value for each combination method is calculated in step S120, a combination method for detecting a fault signal is determined based on the calculated classification result values, and whether the signal of the time series data received later is a normal signal or a fault signal using the classification model of the determined combination method (S130, S140).

Here, in step S140, whether the signal of the received time series data received through the classification model of the determined combination method is a fault signal or a normal signal may be detected or classified, by acquiring the decomposition signals through step S110, extracting the decomposition signal of the determined combination method, and then inputting the extracted decomposition signal to the corresponding classification model.

In some embodiments, in step S130, a combination method corresponding to the best classification result value among the calculated classification result values may be determined.

In some embodiments, the decomposition signal of the determined combination method may include a high-frequency signal having a tendency to noise data among the decomposition signals according to the frequency band.

In some embodiments, the decomposition signal of the determined combination method may include at least one of decomposition signals other than a decomposition signal in a lowest frequency band and a decomposition signal in a highest frequency band among the decomposition signals according to the frequency band. Here, since the decomposition signal of the lowest frequency band means a main pattern of a decomposition target signal, a difference between a normal signal and a fault signal is unclear, and since noise may occur during operation not only in a fault signal but also in a normal signal, the decomposition signal in the highest frequency band may include a signal that may be determined to be such noise. Of course, the decomposition signal in the highest frequency band may be removed from or included in learning data depending on the situation, which may vary depending on the field to which the technology of the present disclosure is applied.

For example, when the decomposition target signal is a signal for detecting the fault of a collaborative robot, a normal vibration signal and a fault vibration signal collected through a gyro sensor and an acceleration sensor may be used as main data. The gyro sensor data and the acceleration sensor data are composed of x, y and z axes and learning data may be composed of a total of 6 columns. The learning model (or classification model) may use a Deep Neural Network (DNN) and the DNN may have a structure as shown in Table 1 below.

TABLE 1

| | Number of Layer | | | |
|---|---|---|---|---|
| Input Size | 1st | 2nd | 3rd | Output Size |
| 1290*6 | 6 | 15 | 7 | 2 |

Of course, in the embodiment of the present disclosure, the classification model is not limited to the DNN structure of Table 1 above.

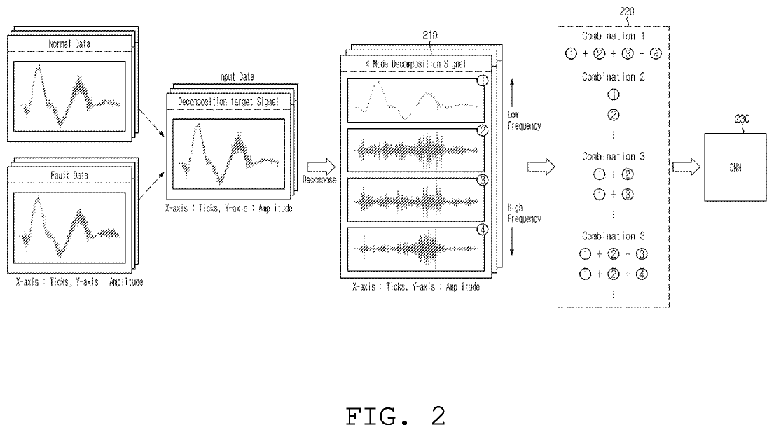

This method of the present disclosure will be described in detail using FIGS. 2 to 5, and it is assumed that there are four decomposition signals. Although it is described that there are four decomposition signals, in the embodiments of the present disclosure, the original signal is not necessarily limited to being decomposed into four signals, and may include more decomposition signals or fewer decomposition signals. The number of decomposition signals may be determined by various variables such as the number of possible combination methods, field of application, and computational cost.

FIG. 2 shows a diagram for explaining the overall process of the method of the present disclosure. As shown in FIG. 2, a process 210 of acquiring four decomposition signals in uniform frequency bands through an FFT technique using a sampling frequency from an original signal, for example, a normal signal or fault signal of time series data, a process 220 of combining the four acquired decomposition signals according to a combination method and a process of acquiring (or calculating) a classification result value of the normal signal or the fault signal according to the combination method using a classification model (or learning model) 230 for the combination method.

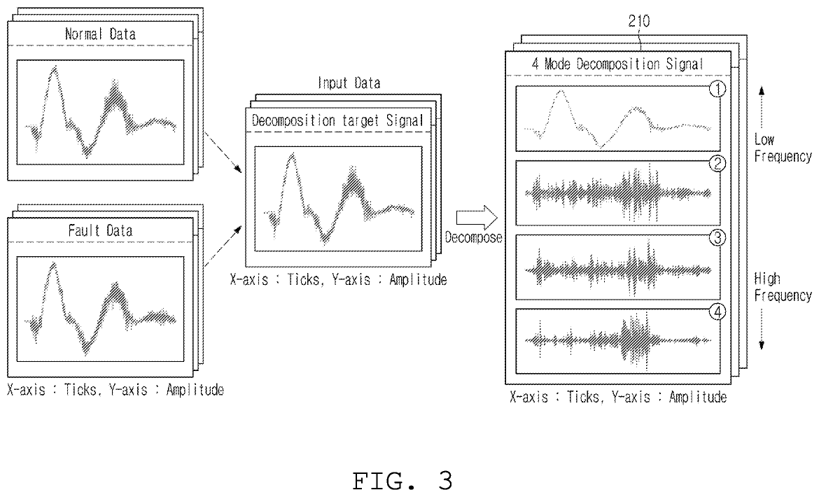

As shown in FIG. 3, the normal signal or fault signal input for decomposition into four decomposition signals has a slight difference in the aspects of the two signals, but the fault signal contains more noise data than the normal signal. Generally, high-frequency signal contains a lot of noise data. Accordingly, embodiments of the present disclosure are to detect fault signals by applying high-frequency signals with a tendency to noise data to learning.

In embodiments of the present disclosure, as shown in FIG. 3, the original data (input data) of the normal signal (normal data) or the fault signal (fault data) is decomposed into four decomposition signals \textcircled{1}, \textcircled{2}, \textcircled{3}, \textcircled{4} with the same bandwidth. Here, since the decomposition signal \textcircled{1} in the lowest frequency band refers to the main pattern of the decomposition target signal, the difference between the normal signal and the fault signal is unclear, and since noise may occur during operation not only in the fault signal but also in the normal signal, the decomposition signal 4 in the highest frequency band may include a signal that may be determined to be such noise. That is, the decomposition signals may be derived sequentially from a low frequency band to a high frequency band.

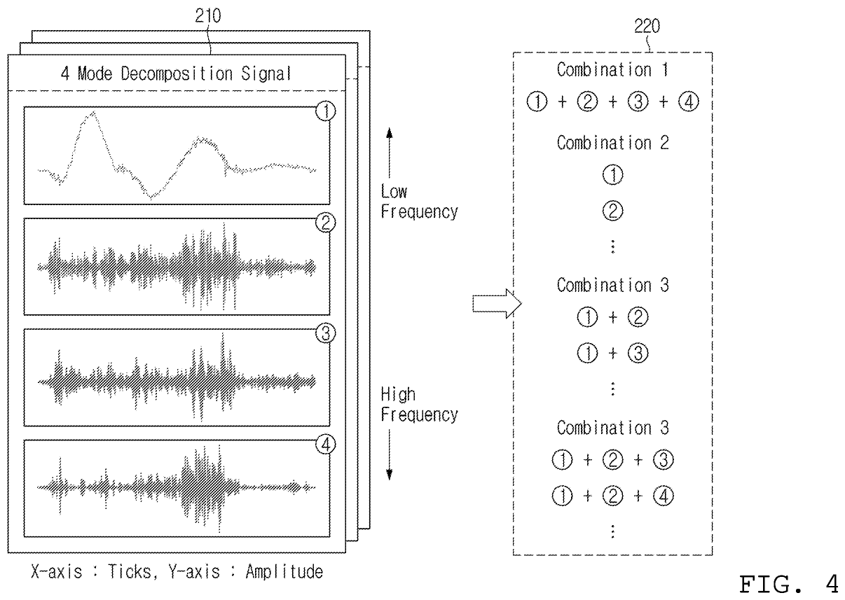

When the four decomposition signals \textcircled{1}, \textcircled{2}, \textcircled{3}, \textcircled{4} are derived, as shown in FIG. 4, the four decomposition signals \textcircled{1}, \textcircled{2}, \textcircled{3}, \textcircled{4} are combined according to preset combination methods. For example, the decomposition signals may be combined using Combination Method 1 (Combination 1), Combination Method 2 (Combination 2), Combination Method 3 (Combination 3), and Combination Method 4 (Combination 4), and the four decomposition signals \textcircled{1}, \textcircled{2}, \textcircled{3}, \textcircled{4} are all added in Combination Method 1, each of the four decomposition signals \textcircled{1}, \textcircled{2}, \textcircled{3}, \textcircled{4} is included in Combination Method 2, two of the four decomposition signals \textcircled{1}, \textcircled{2}, \textcircled{3}, \textcircled{4} are added in Combination Method 3, and three of the four composition signals \textcircled{1}, \textcircled{2}, \textcircled{3}, \textcircled{4} are added in Combination Method 4.

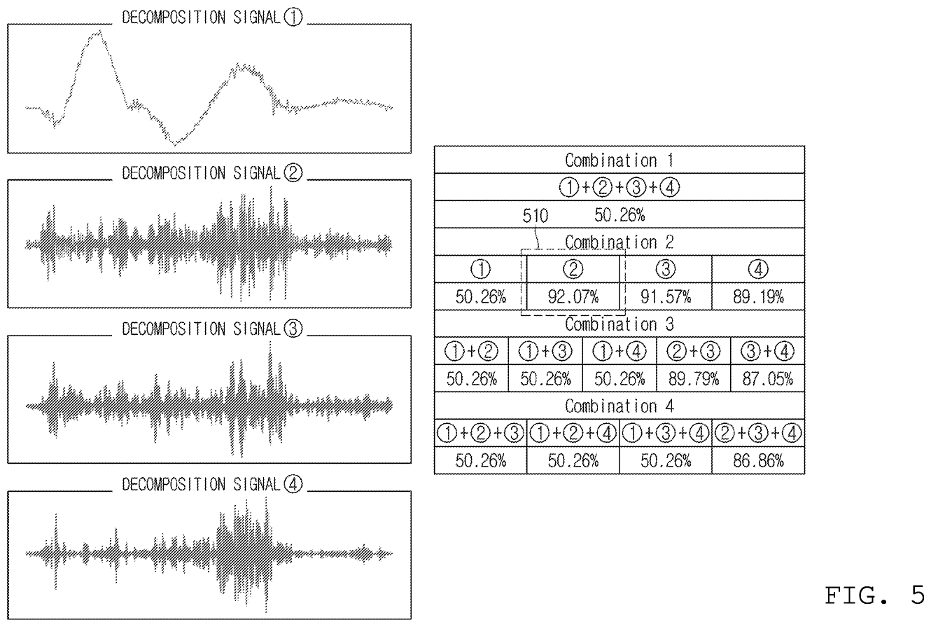

When decomposition signals are added according to Combination Method 1 (Combination 1), Combination Method 2 (Combination 2), Combination Method 3 (Combination 3), and Combination Method 4 (Combination 4), as shown in FIG. 5, a classification result value for detecting whether the original signal input to each classification model is a normal signal or a fault signal is calculated using each classification model according to the combination method. That is, in each classification model for each combination method, a classification result value for detection accuracy of detecting a normal signal as a normal signal or detecting a fault signal as a fault signal is calculated. In the case of FIG. 5, it can be seen that when the decomposition signal \textcircled{2} of the original signal for fault detection is input to the classification model for the learning data of the decomposition signal \textcircled{2}, a classification result value 510 of 92.07% is obtained. It can be seen that this has a higher classification result value than other combination methods. In addition, when the decomposition signal \textcircled{3} of the original signal for fault detection is input to the classification model for the learning data of decomposition signal \textcircled{3}, it can be seen that a classification result value of 91.57% is obtained, which is the second highest classification result value.

In addition, since the \textcircled{1}+\textcircled{2}+\textcircled{3}+\textcircled{4} signal, which is the sum of all the decomposition signals, is the same as the original signal, it can be seen that 50.26%, which is the performance of the original signal will be derived. In the case of the original signal, it can be seen that the features of the normal signal and the fault signals are unclear and thus the performance is low.

The decomposition signal \textcircled{1} is a signal in the lowest frequency band and refers to the main pattern of the decomposition target signal. Therefore, the difference between normal and fault signals is unclear and the performance of 50.26% is derived. In the case of the decomposition signals \textcircled{2}, \textcircled{3}, and \textcircled{4} corresponding to the high-frequency signal capable of classifying the normal signal and the fault signal, it can be seen that the features of the normal signal and the fault signal show clearly different aspects and thus high performance is derived.

When the decomposition signal \textcircled{1} is included, the difference in features between the normal signal and the fault signal is unclear, 50.26%, which is the performance of the original signal, is derived. In the case of the decomposition signals \textcircled{2}, \textcircled{3}, and \textcircled{4} excluding the decomposition signal \textcircled{1}, the normal and fault features are clear so that higher performance of up to 41.81% is derived compared to the performance of the original signal.

As in Combination Method (Combination 4), if the decomposition signal \textcircled{1}, in which the difference in features between the normal signal and the fault signal is unclear, is included, low performance is derived. In the case of the decomposition signals \textcircled{2}, \textcircled{3}, \textcircled{4}, the normal features and fault features are clear, so that higher performance of 36.6% is derived compared to the performance of the original signal.

As shown in FIG. 5, it can be seen that high performance for detection of the fault signal is derived when the decomposition signals \textcircled{2} and \textcircled{3} are included. In addition, noise occurs during operation not only in the fault signal but also in the normal signal. The signal that may be determined to be noise are mainly included in the decomposition signal \textcircled{4} in the high-frequency band. Therefore, it can be seen that when the decomposition signals \textcircled{2} and \textcircled{3} are used to classify the normal signal and the fault signal, the fault features are clearer than in the decomposition signal \textcircled{4}, showing high performance.

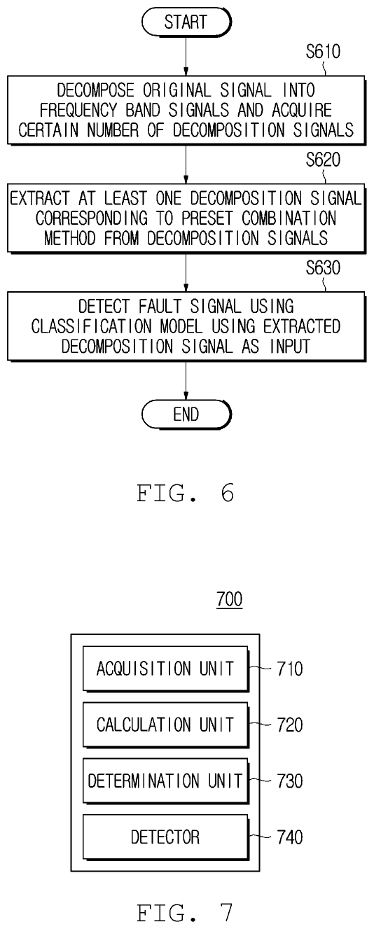

FIG. 6 is a flowchart illustrating operation of a fault signal detection method according to another embodiment of the present disclosure, which shows a combination method for detecting a fault signal through the above-described process and a process of determining a classification model and then detecting a fault signal using the determined classification model.

Referring to FIG. 6, in the fault signal detection method according to another embodiment of the present disclosure, the original signal of the time series data to detect the fault signal is decomposed to a certain number of frequency band signals, and decomposition signals according to the frequency band are acquired (S610).

In some embodiments, in step S610, after setting a sampling frequency, the normal signal or fault signal is decomposed into a certain number (for example, N) of uniform frequency band signals to acquire decomposition signals according to the frequency band. Through this process, the aspect of the decomposition signal according to the frequency band may be analyzed, and the features of the fault may be extracted more clearly.

In some embodiments, in step S610, a certain number of decomposition signals may be acquired using a Fast Fourier Transform (FFT) technique. For example, in step S610, by reconstructing a negative frequency signal using a complex conjugate relationship of the frequency signal based on RFFT among the FFT techniques, the decomposition signals according to a uniform frequency band may be acquired from the original signal.

When the decomposition signals according to the uniform frequency band is acquired in step S610, at least one decomposition signal corresponding to a preset combination method is extracted from the decomposition signals (S620).

Here, the preset combination method may mean a combination method of decomposition signals used to learn a classification model for detecting a fault signal, and may include the combination method determined in step S130 of FIG. 1.

When the decomposition signal corresponding to the preset combination method is extracted in step S620, whether the original signal is a fault signal is detected or classified using an already learned classification model that uses the at least one extracted decomposition signal as input (S630).

Although the description is omitted in the method of FIG. 6, a method according to another embodiment of the present disclosure may include all descriptions of the method of FIGS. 1 to 5, which can be understood by those skilled in the art.

As such, in the method according to the embodiments of the present disclosure, to prevent duplication of the decomposition signals, the signal may be decomposed into uniform frequency bands, an optimal decomposition signal combination among the frequency band decomposition signals may be determined, and the faulty signal may be detected using a classification model for the optimal decomposition signal combination.

In addition, in the method according to embodiments of the present disclosure, data useful for learning may be reflected by combining decomposition signals, and through this, the normal signal or fault signal may be evaluated with respect to the original signal of the time series data, thereby verifying the performance and reliability of the model. That is, in the method according to the embodiments of the present disclosure, a combination that can more clearly detect the fault features of the decomposition target signal may be selected as a combination signal, and the selected combination signal may be used as input data of a classification model for fault detection, such as a DNN model, to check the performance of time series data, for example, motor fault detection of an industrial robot.

In addition, in the method according to embodiments of the present disclosure, it is possible to clearly extract fault features of a signal of time series data, in which the features of a normal signal and a fault signal are not clear, through a decomposition signal decomposed into uniform bands.

In the method according to the embodiments of the present disclosure, when developing a signal analysis technique for detecting a fault signal, for example, a motor fault of an industrial robot widely used in an industrial environment, various fault detection models for improving performance reliability are applicable and are applicable in data preprocessing when a classification model using the features of a signal is necessary without being limited to fault detection.

In addition, although, in the method according to the embodiments of the present disclosure, the classification result values for the remaining decomposition signals excluding the decomposition signal in the highest frequency band and the decomposition signal in the lowest frequency band of the original signal are high, the classification result values is not necessarily low in the decomposition signal in the highest frequency band and the decomposition signal in the lowest frequency band, and the optimal combination method may vary depending on the field of application. That is, the method according to the embodiments of the present disclosure is not limited to determining the optimal combination by the remaining decomposition signals excluding the decomposition signal in the highest frequency band and the decomposition signal in the lowest frequency band, and the optimal combination method may be determined based on the classification result value calculated during the process of learning the classification model of each combination method.

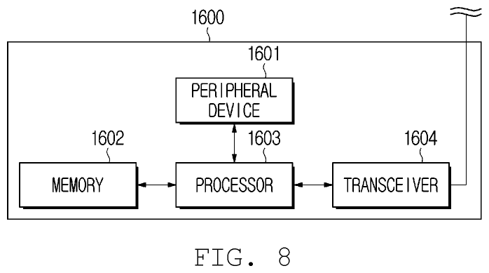

FIG. 7 is a diagram illustrating a configuration of a fault signal detection apparatus according to another embodiment of the present disclosure, and shows the configuration of the apparatus for performing the method of FIG. 1.

Referring to FIG. 7, the fault signal detection apparatus 700 according to another embodiment of the present disclosure includes an acquisition unit 710, a calculation unit 720, a determination unit 730 and a detector 740.

The acquisition unit 710 decomposes an original signal in the time domain, for example, an original signal of time series data, into a certain number of frequency band signals, and acquires decomposition signals according to the frequency band.

In some embodiments, the acquisition unit 710 may set a sampling frequency and then decompose a normal signal or a fault signal into a certain number (e.g., N) of uniform frequency band signals to acquire the decomposition signals according to the frequency band.

In some embodiments, the acquisition unit 710 may acquire the certain number of decomposition signals using a Fast Fourier Transform (FFT) technique, and, for example, the acquisition unit 710 may reconstruct a negative frequency signal using a complex conjugate relationship of the frequency signal based on Real-valued FFT (RFFT) among FFT techniques, thereby acquiring the decomposition signals according to the uniform frequency band from the original signal.

The calculation unit 720 combines the certain number of decomposition signals using preset combination methods and calculates a classification result value for classifying the original signal into the normal signal or the fault signal using a classification model using at least one decomposition signal included in the combination methods as input.

In some embodiments, the calculation unit 720 may calculate a classification result value for each combination method through each classification model using learning data for at least one decomposition signal combined according to the combination method.

In some embodiments, the calculation unit 720 may calculate a classification result value for each combination method through a specific classification model through learning data unrelated to the combination method.

The determination unit 730 determines a combination method for detecting a fault signal based on the calculated classification result values.

In some embodiments, the determination unit 730 may determine a combination method to include a high-frequency signal having a tendency to noise data among the decomposition signals according to the frequency band.

In some embodiments, the determination unit 730 may determine a combination method to include at least one of the remaining decomposition signals excluding the decomposition signal in the lowest frequency band and the decomposition signal in the highest frequency band among the decomposition signals according to the frequency band.

In some embodiments, the determination unit 730 may determine a combination method corresponding to a highest classification result value among the calculated classification result values.

The detector 740 detects whether the signal of the time series data received later is a normal signal or a fault signal using the classification model of the determined combination method.

In some embodiments, the detector 740 may detect or classify whether the signal of the time series signal is a fault signal or a normal signal through the classification model of the determined combination method, by acquiring the decomposition signals from the signal of the time series data for detecting the fault signal through the acquisition unit 710, extracting the decomposition signal of the combination method determined by the determination unit 730 and inputting the extracted decomposition signal to the classification model.

Although the description is omitted in the apparatus of the present disclosure, the apparatus according to the embodiment of the present disclosure may include all description of the method of FIGS. 1 to 6, which are obvious to those skilled in the art.

FIG. 8 is a diagram illustrating a configuration of a device, to which a fault signal detection apparatus is applied, according to another embodiment of the present disclosure.

For example, the fault signal detection apparatus according to another embodiment of the present disclosure shown in FIG. 7 may be the device 1600 of FIG. 8. Referring to FIG. 8, the device 1600 may include a memory 1602, a processor 1603, a transceiver 1604 and a peripheral device 1601. In addition, for example, the device 1600 further include other components, is not limited to the above-described embodiment. In this case, the device 1600 may be, for example, a movable user terminal (e.g., smartphone, laptop, wearable device, etc.) or a fixed management device (e.g., server, PC, etc.).

More specifically, the device 1600 of FIG. 8 may be an exemplary hardware/software architecture, such as a motor fault detection apparatus, a classification model learning apparatus, etc. At this time, as an example, the memory 1602 may be a non-removable memory or a removable memory. In addition, as an example, the peripheral device 1601 may include a display, GPS, or other peripheral devices, and is not limited to the above-described embodiment.

In addition, as an example, the above-described device 1600 may include a communication circuit like the transceiver 1604, and may communicate with an external device based on this.

In addition, for example, the processor 1603 may be at least one of general-purpose processors, digital signal processors (DSPs), DSP cores, controllers, microcontrollers, application specific integrated circuits (ASICs), field programmable gate array (FPGA) circuits, or any other type of integrated circuits (ICs) or one or more microprocessors associated with a state machine. In other words, it may be a hardware/software configuration for controlling the device 1600 described above. In addition, the processor 1603 may modularize and perform the functions of the acquisition unit 710, the calculation unit 720, the determination unit 730, and the detector 740 of FIG. 7 described above.

At this time, the processor 1603 may execute computer-executable instructions stored in the memory 1602 to perform various essential functions of the fault signal detection apparatus. As an example, the processor 1603 may control at least one of signal coding, data processing, power control, input/output processing, or communication operations. In addition, the processor 1603 may control a physical layer, a MAC layer, and an application layer. In addition, as an example, the processor 1603 may perform authentication and security procedures at the access layer and/or application layer, and is not limited to the above-described embodiment.

As an example, the processor 1603 may communicate with other apparatuses through the transceiver 1604. As an example, the processor 1603 may control the fault signal detection apparatus to communicate with other apparatuses through a network through execution of computer-executable instructions. That is, communication performed in the present disclosure may be controlled. As an example, the transceiver 1604 may transmit an RF signal through an antenna and may transmit signals based on various communication networks.

In addition, as an example, MIMO technology, beamforming, etc. may be applied as antenna technology, and is not limited to the above-described embodiment. In addition, signals transmitted and received through the transceiver 1604 may be modulated and demodulated and controlled by the processor 1603, and are not limited to the above-described embodiment.

While the exemplary methods of the present disclosure described above are represented as a series of operations for clarity of description, it is not intended to limit the order in which the steps are performed, and the steps may be performed simultaneously or in different order as necessary. In order to implement the method according to the present disclosure, the described steps may further include other steps, may include remaining steps except for some of the steps, or may include other additional steps except for some steps.

The various embodiments of the present disclosure are not a list of all possible combinations and are intended to describe representative aspects of the present disclosure, and the matters described in the various embodiments may be applied independently or in combination of two or more.

Various embodiments of the present disclosure may be implemented in hardware, firmware, software, or a combination thereof. In the case of implementing the present disclosure by hardware, the present disclosure can be implemented with application specific integrated circuits (ASICs), Digital signal processors (DSPs), digital signal processing devices (DSPDs), programmable logic devices (PLDs), field programmable gate arrays (FPGAs), general processors, controllers, microcontrollers, microprocessors, etc.

The scope of the present disclosure includes a non-transitory computer-readable medium in which software or machine-executable instructions (e.g., operating system, application, firmware, program, etc.) that cause operations according to the methods of various embodiments to be executed on an apparatus or computer and such software or instructions are stored and may be executed on an apparatus or computer.

According to the present disclosure, it is possible to provide a method and apparatus for determining an optimal decomposition signal combination among frequency band decomposition signals and detecting a fault signal using a classification model based on the optimal decomposition signal combination.

The effects that can be obtained from the present disclosure are not limited to the effects mentioned above, and other effects not mentioned can be clearly understood by those skilled in the art from the description below.

What is claimed is:

1. A fault signal detection method comprising:
acquiring decomposition signals according to a frequency band, by decomposing an original signal in the time domain into a certain number of frequency band signals;
combining the certain number of decomposition signals and calculating a classification result value for classifying the original signal into a normal signal or a fault signal using a classification model using at least one decomposition signal included in a combination method as input; and
determining a combination method for detecting a fault signal based on classification result values of the classification model.

2. The fault signal detection method of claim 1,
wherein the combination method comprises a method of adding at least one of the decomposition signals.

3. The fault signal detection method of claim 1, further comprising:
determining a classification model learned by a decomposition signal of the determined combination method; and
detecting a fault signal using the determined classification model.

4. The fault signal detection method of claim 1, wherein the decomposition signal of the determined combination method comprises a high-frequency signal having a tendency to noise data among the decomposition signals according to the frequency band.

5. The fault signal detection method of claim 1, wherein the decomposition signal of the determined combination method comprises at least one of the remaining decomposition signals excluding a decomposition signal in a lowest frequency band and a decomposition signal in a highest frequency band among the decomposition signals according to the frequency band.

6. The fault signal detection method of claim 1, wherein the acquiring the decomposition signals comprises acquiring the certain number of decomposition signals by decomposing the original signal into uniform frequency bands.

7. The fault signal detection method of claim 1, wherein the acquiring the decomposition signals comprises acquiring the certain number of decomposition signals using a Fast Fourier Transform (FFT) technique.

8. The fault signal detection method of claim 7, wherein the acquiring the decomposition signals comprises acquiring the decomposition signals by reconstructing a negative frequency signal using a complex conjugate relationship of a frequency signal based on Real-valued FFT (RFFT) among the Fast Fourier Transform (FFT) techniques.

9. A fault signal detection method comprising:
acquiring decomposition signals according to a frequency band by decomposing an original signal in the time domain into a certain number of frequency band signals;
extracting at least one decomposition signal corresponding to a preset combination method from the decomposition signals; and
classifying the original signal into a normal signal or a fault signal, using a pre-learned classification model using the extracted at least one decomposition signal as input.

10. The fault signal detection method of claim 9, wherein the extracting comprises extracting at least one of the remaining decomposition signals excluding a decomposition signal in a lowest frequency band and a decomposition signal in a highest frequency band from the decomposition signals.

11. The fault signal detection method of claim 9, wherein the acquiring the decomposition signals comprises acquiring the certain number of decomposition signals using a Fast Fourier Transform (FFT) technique.

12. The fault signal detection method of claim 11, wherein the acquiring the decomposition signals comprises acquiring the decomposition signals by reconstructing a negative frequency signal using a complex conjugate relationship of a frequency signal based on Real-valued FFT (RFFT) among the Fast Fourier Transform (FFT) techniques.

13. A fault signal detection apparatus comprising:
an acquisition unit configured to acquire decomposition signals according to a frequency band, by decomposing an original signal in the time domain into a certain number of frequency band signals;
a calculation unit configured to combine the certain number of decomposition signals and to calculate a classification result value for classifying the original signal into a normal signal or a fault signal using a classification model using at least one decomposition signal included in a combination method as input; and
a determination unit configured to determine a combination method for detecting a fault signal based on classification result values of the classification model.

14. The fault signal detection apparatus of claim 13,
wherein the combination method comprises a method of adding at least one of the decomposition signals.

15. The fault signal detection apparatus of claim 13,
wherein the determination unit determines a classification model learned by a decomposition signal of the determined combination method, and
wherein the fault signal detection apparatus further comprises a detector configured to detect a fault signal using the determined classification model.

16. The fault signal detection apparatus of claim 13, wherein the decomposition signal of the determined combination method comprises a high-frequency signal having a tendency to noise data among the decomposition signals according to the frequency band.

17. The fault signal detection apparatus of claim 13, wherein the decomposition signal of the determined combination method comprises at least one of the remaining decomposition signals excluding a decomposition signal in a lowest frequency band and a decomposition signal in a highest frequency band among the decomposition signals according to the frequency band.

18. The fault signal detection apparatus of claim 13, wherein the acquisition unit acquires the certain number of decomposition signals by decomposing the original signal into uniform frequency bands.

19. The fault signal detection apparatus of claim 13, wherein the acquisition unit acquires the certain number of decomposition signals using a Fast Fourier Transform (FFT) technique.

20. The fault signal detection apparatus of claim 19, wherein the acquisition unit acquires the decomposition signals by reconstructing a negative frequency signal using a complex conjugate relationship of a frequency signal based on Real-valued FFT (RFFT) among the Fast Fourier Transform (FFT) techniques.
